(19) United States
(12) Patent Application Publication
(10) Pub. No.: US 2025/0096742 A1
(43) Pub. Date: Mar. 20, 2025

(54) Interstage Clamping Circuit

(71) Applicant: Qualcomm Incorporated, San Diego, CA (US)

(72) Inventor: Lei Ma, Palo Alto, CA (US)

(21) Appl. No.: 18/470,139

(22) Filed: Sep. 19, 2023

(51) Int. Cl. H03F 1/56; H03F 3/24

(52) U.S. Cl. CPC H03F 1/565; H03F 3/245; H03F 2200/222; H03F 2200/387; H03F 2200/451

(57) ABSTRACT

An apparatus is disclosed for implementing a clamping circuit with an interstage matching network or between two amplifier stages to provide power clamping. In example aspects, the apparatus includes an amplifier circuit having an input port and an output port. The amplifier circuit includes a driver amplifier, an interstage matching network, a power amplifier, and a clamping circuit. The driver amplifier includes a driver amplifier output and is coupled between the input port and the output port. The power amplifier includes a power amplifier input and is coupled between the driver amplifier output and the output port. The interstage matching network is coupled between the driver amplifier output and the power amplifier input. The clamping circuit includes a transistor and a resistor coupled thereto. The clamping circuit is coupled to the interstage matching network via a node that is coupled between the driver amplifier output and the power amplifier input.

### TECHNICAL FIELD

This disclosure relates generally to signal communication or signal processing using an electronic device and, more specifically, to employing a clamping circuit between two amplifier stages, such as with an interstage matching network.

### BACKGROUND

Electronic devices include traditional computing devices such as desktop computers, notebook computers, smartphones, wearable devices like a smartwatch, internet servers, and so forth. Electronic devices also include other types of computing devices such as personal voice assistants (e.g., smart speakers), wireless access points or routers, thermostats and other automated controllers, robotics, automotive electronics, devices embedded in other machines like refrigerators and industrial tools, Internet of Things (IoT) devices, medical devices, and so forth. These various electronic devices provide services relating to productivity, communication, social interaction, security, health and safety, remote management, entertainment, transportation, and information dissemination. Thus, electronic devices play crucial roles in modern society.

Many of the services provided by electronic devices in today's interconnected world depend at least partly on electronic communications. Electronic communications can include, for example, those exchanged between two or more electronic devices using wireless or wired signals that are transmitted over one or more networks, such as the Internet, a Wi-Fi® network, or a cellular network. Electronic communications can therefore include wireless or wired transmissions and receptions. To transmit and receive communications, an electronic device can use a transceiver, such as a wireless transceiver that is designed for wireless communications.

Electronic communications can therefore be realized by propagating signals between two wireless transceivers at two different electronic devices. For example, using a wireless transmitter, a smartphone can transmit a wireless signal to a base station over the air as part of an uplink communication to support mobile services. Using a wireless receiver, the smartphone can receive a wireless signal that is transmitted from the base station via the air medium as part of a downlink communication to enable mobile services. With a smartphone, mobile services can include making voice and video calls, participating in social media interactions, sending messages, watching movies, sharing videos, and performing searches. Other mobile services can include using map information or navigational instructions, finding friends, engaging in location-based services generally, transferring money, obtaining another service like a car ride, and so forth.

Many of these mobile services depend at least partly on the transmission or reception of wireless signals between two or more electronic devices. Consequently, researchers, electrical engineers, and designers of electronic devices strive to develop wireless transceivers and other wireless hardware that can use wireless signals effectively to provide these and other mobile services.

### SUMMARY

A power clamp can protect the components of a wireless interface device. In one approach, a power clamp is employed on a controller die to protect a power amplifier that is on a different integrated circuit die. The routing distance between such a power clamp on the controller die and the power amplifier on an amplifier die, however, is sufficient to degrade the power clamping that is actually provided at the power amplifier to a level that is below a targeted power clamping protection threshold. To shorten this routing distance and at least reduce the disparity between a targeted and an achieved protection level, this document describes employing a clamping circuit between two amplifier stages, such as in conjunction with an interstage matching network. In some cases, the interstage matching network can be coupled between a driver amplifier and a power amplifier, and the clamping circuit can provide power clamping to protect the power amplifier. In example implementations, an integrated circuit die can include an amplifier circuit having a driver amplifier that feeds a power amplifier. The integrated circuit die also includes a clamping circuit that can be coupled along a signal chain between the driver amplifier and the power amplifier via a node, which may be part of an interstage matching network coupled between the two amplifiers. In example operations, multiple diodes and multiple transistors are coupled together into a differential clamping circuit that can clamp a voltage level of the node. The clamping circuit can also clamp a current, which is flowing from an output of the driver amplifier, before the current “reaches” an input of the power amplifier. In some cases, a respective resistor is coupled to each transistor of a pair of cross-coupled transistors of the differential clamping circuit. These resistors can increase a balance between clamping positive and negative voltage swings, including with differential signaling. Thus, the clamping circuit can provide power clamping for the amplifier circuit, such as for the power amplifier that is coupled “downstream” of an output of the driver amplifier. Further, the power clamping can be achieved while having an appreciably shorter routing distance between the power clamp and the power amplifier. These and other example aspects for an interstage clamping circuit are described herein.

In an example aspect, an apparatus is disclosed. The apparatus includes an amplifier circuit having an input port and an output port. The amplifier circuit includes a driver amplifier, a power amplifier, an interstage matching network, and a clamping circuit. The driver amplifier includes a driver amplifier output and is coupled between the input port and the output port. The power amplifier includes a power amplifier input and is coupled between the driver amplifier output and the output port. The interstage matching network is coupled between the driver amplifier output and the power amplifier input. The clamping circuit is coupled to the interstage matching network via a node that is coupled between the driver amplifier output and the power amplifier input. The clamping circuit includes a transistor and a resistor coupled to the transistor.

In an example aspect, an apparatus for clamping power in conjunction with an interstage matching network is disclosed. The apparatus includes an amplifier circuit having an input port and an output port. The amplifier circuit includes a driver amplifier, a power amplifier, and interstage matching network. The driver amplifier includes a driver amplifier input and a driver amplifier output, with the driver amplifier input coupled to the input port. The power amplifier includes a power amplifier input and a power amplifier output, with the power amplifier output coupled to the output port. The interstage matching network is coupled between the driver amplifier output and the power amplifier input. The amplifier circuit also includes means for clamping a power of a signal flowing through the interstage matching network between the driver amplifier and the power amplifier using a transistor and a resistor coupled to the transistor.

In an example aspect, a method for clamping power by a clamping circuit with respect to an amplifier circuit or for operating a power clamp that is coupled to an interstage matching network is disclosed. The method includes amplifying, using a driver amplifier, a signal to produce a first amplified signal. The method also includes propagating the first amplified signal through an interstage matching network. The method additionally includes clamping, in conjunction with the propagating, the first amplified signal to produce an intermediate signal using a transistor and a resistor coupled to the transistor. The method further includes amplifying, using a power amplifier, the intermediate signal to produce a second amplified signal.

### BRIEF DESCRIPTION OF DRAWINGS

FIG. 1 illustrates an environment with an example electronic device that has a wireless interface device, which includes at least one example amplifier circuit with a clamping circuit.

FIG. 2 is a schematic diagram illustrating an example radio-frequency (RF) front-end and an example transceiver that can each include at least one amplifier circuit with a clamping circuit.

FIG. 3 is a schematic diagram illustrating an example amplifier die including an amplifier circuit, which has an interstage matching network coupled between a driver amplifier and a power amplifier, and a clamping circuit coupled to the interstage matching network.

FIG. 4 is a circuit diagram illustrating an example clamping circuit, which may be coupled to an interstage matching network of an amplifier circuit to provide power clamping in single-ended or differential implementations.

FIG. 5 is a circuit diagram illustrating an example differential clamping circuit, which may be coupled to an interstage matching network of an amplifier circuit to provide power clamping.

FIGS. 6-1 and 6-2 jointly depict a circuit diagram illustrating an example differential amplifier circuit with a driver amplifier, an interstage matching network, and a power amplifier and with multiple example nodes at which a differential clamping circuit can be coupled to provide power clamping.

FIG. 7 is a flow diagram illustrating an example process for clamping power by a clamping circuit with respect to an amplifier circuit or for operating a power clamp that is coupled to an interstage matching network.

### DETAILED DESCRIPTION

### Introduction and Overview

To facilitate transmission and reception of wireless signals, an electronic device can use a wireless interface device that includes a wireless transceiver and/or a radio-frequency (RF) front-end. The wireless interface device includes various electrical and electronic components that operate based on voltages and currents and that process signals using such voltages and currents. These components are designed to operate within specified ranges of voltages and currents. If the operating conditions deviate from these specified ranges, the components may produce faulty signaling. Moreover, deviations from specified operating conditions can damage the components, especially if the operational current or voltage is higher than the corresponding specified range.

To protect components of a circuit, such as the transistors used for amplification or switching, a circuit can include a power clamp. A power clamp can prevent the power experienced by a component from exceeding an amount of power that can damage the component. To do so, the power clamp can limit a voltage level or a current magnitude. This may include limiting voltage and current in accordance with a permitted, but optional, interpretation of the word “or” as encompassing an “inclusive or” relationship. In some cases, a power clamp can also or instead be used to provide, for example, over-voltage protection or electrostatic discharge (ESD) protection.

In certain wireless interface device environments, some control functionality is separated from at least a portion of amplifier functionality. For example, a controller die can be separate from an amplifier die. The controller die may be realized with complementary metal-oxide-semiconductor (CMOS) or silicon on insulator (SOI) process technology, just to name a couple of examples. The amplifier die includes an amplifier circuit (or amplification circuit) that can include a driver amplifier and a power amplifier. Prior to amplification by the amplifier die, the controller die can condition a signal, such as a radio-frequency signal (RF signal), using a filter, a pre-driver amplifier, a combination thereof, and so forth.

In one approach to protecting circuit components, an input clamp is deployed at the controller die to meet power protection specifications for the components of the controller die and the amplifier die. With the input clamp on the controller die, however, the routing of the RF input signal is relatively extensive relative to reaching the components on the amplifier die. The RF input signal enters the controller die and propagates through multiple blocks or stages to condition the signal. These blocks can include an input attenuator, the input clamp, an input switch, a pre-driver amplifier, and so forth. The conditioned RF signal then exits from the controller die and travels to the amplifier die, which includes the power amplifier. This appreciable routing distance creates problems with the RF signal. First, the routing distance degrades the quality of the signal itself, such as by altering the phase of the signal. Second, the routing distance shifts a target power-clamping protection threshold to an actual power-clamping protection threshold that may be lower than the targeted one.

This leaves components of the amplifier die, including the power amplifier, vulnerable to damage from higher-than-specified voltages and currents. Accordingly, the power amplifier circuitry can be damaged, and the die can become useless. A die that is discovered to be useless during testing at a manufacturing facility results in financial loss. Further, a die that becomes damaged after being deployed in an electronic device causes still more harm as a consumer electronic device, such as a cell phone, may be rendered inoperable and returned by the consumer.

To at least reduce this routing distance between an input power clamp and a power amplifier, this document describes other approaches to protecting circuit components in which a power clamp is incorporated into an integrated circuit die (or integrated circuit chip) having a driver amplifier or a power amplifier. This amplifier die, or at least one or more transistors thereof, can be realized using gallium arsenide (GaAs) semiconductor technology, for instance. The power clamp can be coupled to a node of an amplifier circuit of the amplifier die. In some aspects, the amplifier circuit includes a driver amplifier that feeds a power amplifier. The node may be coupled between the driver amplifier and the power amplifier.

In some cases, an interstage matching network can be coupled between the driver amplifier and the power amplifier. In at least some of such cases, the node may be associated with the interstage matching network. For example, the node may be part of a wire, a metallic trace, or another electrical conductor that forms at least a portion of the interstage matching network or that couples together two or more components thereof. Thus, a power clamp can be coupled to the interstage matching network between the driver amplifier and the power amplifier.

In some implementations, the power clamp can be realized with a clamping circuit. The clamping circuit includes at least one transistor coupled between a first node, such as the node associated with the interstage matching network, and a second node, such as another node of the amplifier circuit (e.g., for a differential power amplifier). The other node of the amplifier circuit may also be associated with the interstage matching network. The clamping circuit can further include one or more diodes coupled together in series and at least one resistor coupled to the at least one transistor, as is described below. A quantity of one or more series-connected diodes can establish, at least partly, a trigger point for the power clamp. The clamping circuit can limit a voltage level at the node or a current magnitude flowing through the node toward an input of the power amplifier based on the trigger point of the power clamp.

A second clamping circuit coupled to the node “in an opposite manner” relative to transistor terminals or diode junctions can protect against opposite voltages. In other words, a first clamping circuit can protect against positive or forward signal swings, and a second clamping circuit can protect against negative or reverse signal swings. In some implementations, these two clamping circuits can also be combined to realize a differential clamping circuit to protect a differential amplifier, such as a differential power amplifier.

Thus, certain described implementations include an input power clamp that is disposed on a same die as a power amplifier, which is part of an amplifier circuit. The power clamp can be realized with a clamping circuit or can be coupled to an interstage matching network of the amplifier circuit, including may be realized with a clamping circuit that is coupled to an interstage matching network of the amplifier circuit. The clamping circuit can provide voltage or current clamping as a power clamp at the interstage matching network of the amplifier circuit between a driver amplifier and the power amplifier. This clamping at the interstage matching network can therefore limit the power input to the power amplifier, which “follows” the driver amplifier and the interstage matching network from a signal flow or signal processing perspective.

At least the power amplifier portion of the amplifier circuit can be realized with single-ended or differential circuitry. For a differential power amplifier, this document describes how an interstage clamping circuit can be used to decrease the size of the clamping-voltage steps that are available to a circuit designer. Accordingly, certain described implementations can enable a finer control over a designed clamping voltage. Further, the resistor of the clamping circuit can facilitate a more balanced clamping, including with differential power amplifiers. For example, including a resistor that is coupled between two terminals of the transistor of the clamping circuit can cause the positive and negative power clamping levels to be closer to being equal as compared to a clamping circuit that omits such a resistor.

The on-die power clamping approach as described herein provides an appreciably shorter routing distance between the power clamp and the power amplifier along the RF signal chain. This shorter routing distance is achieved without appreciably increasing the size of the amplifier die. Accordingly, a targeted power-clamping protection threshold can be achieved at the power amplifier with more certainty and with less signal degradation. Further, overall product cost is reduced by omitting or removing the power clamp from the controller die.

A clamping circuit as described herein can therefore be coupled to an interstage-matching-network stage cell via at least one node to provide an input clamping function for at least the power amplifier. Example implementations of at least a differential-configuration-based power clamp can provide opportunities for finer control of a triggering point for the power clamping at an input of the power amplifier via a node of the interstage matching network. Further, including a resistor that is coupled to a transistor of the clamping circuit can produce a more-balanced clamping effect between the plus and minus portions of the differential amplifier circuit or the differential signaling thereof. Moreover, a stronger clamping effect can be implemented (e.g., enforced or enacted) as a voltage at the node increases, which provides superior protection. Additional example implementations for employing a clamping circuit with an interstage matching network to provide power clamping protection are described herein.

### Description Examples

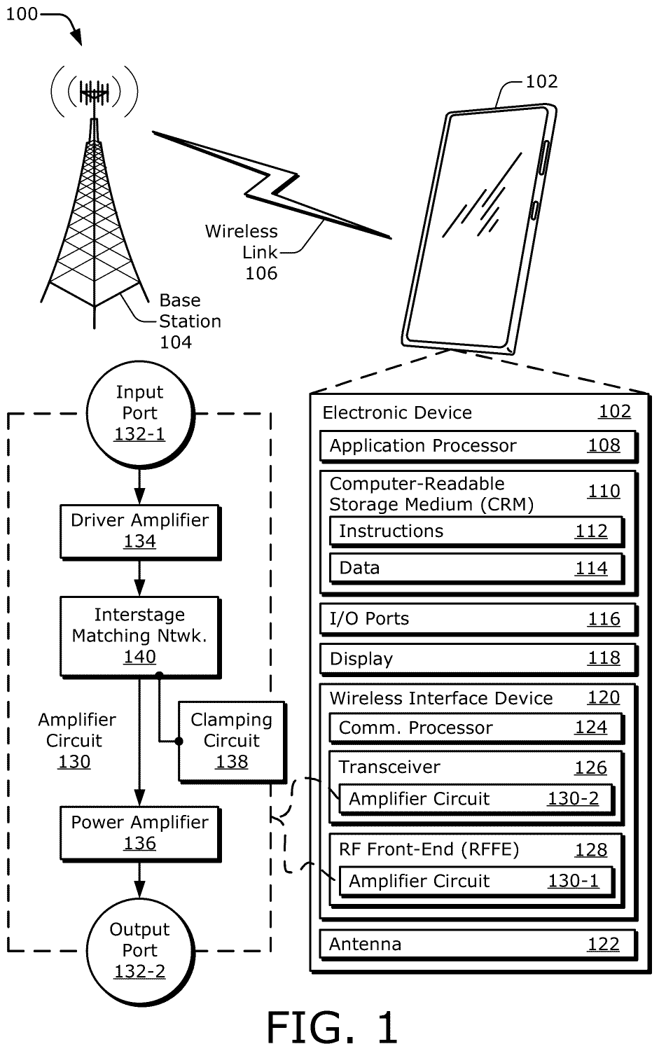

FIG. 1 illustrates an example environment 100 with an electronic device 102 that has a wireless interface device 120, which includes at least one example amplifier circuit 130 with a clamping circuit 138. This document describes example implementations of the amplifier circuit 130, which may be part of a transceiver, a radio-frequency front-end (RFFE), and so forth of an apparatus. In the environment 100, the example electronic device 102 communicates with a base station 104 through a wireless link 106.

In FIG. 1, the electronic device 102 is depicted as a smartphone. The electronic device 102, however, may be implemented as any suitable computing or other electronic device. Examples of an apparatus that can be realized as an electronic device 102 include a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, fitness management device, wearable device such as intelligent glasses or smartwatch, wireless power device (transmitter or receiver), medical device, and so forth.

The base station 104 communicates with the illustrated smartphone realization of the electronic device 102 via the wireless link 106, which may be implemented as any suitable type of wireless link that carries a communication signal. Although depicted as a base station tower of a cellular radio network, the base station 104 may represent or be implemented as another device, such as a satellite, terrestrial broadcast tower, access point, peer-to-peer device, mesh network node, fiber optic line interface, another electronic device as described above generally, and so forth. Hence, the wireless link 106, or an extension thereof, can connect between the electronic device 102 and the base station 104 in any of various manners.

The wireless link 106 can include a downlink of data or control information communicated from the base station 104 to the electronic device 102. The wireless link 106 can also include an uplink of other data or control information communicated from the electronic device 102 to the base station 104. The wireless link 106 may be implemented using any suitable wireless communication protocol or standard. Examples of such protocols and standards include a 3^{rd} Generation Partnership Project (3GPP) Long-Term Evolution (LTE) standard, such as a 4^{th} Generation (4G), a 5^{th} Generation (5G), or a 6^{th} Generation (6G) cellular standard; an IEEE 802.11 standard, such as 802.11g, ac, ax, ad, aj, or ay standard (e.g., Wi-Fi® 6 or WiGig®); an IEEE 802.16 standard (e.g., WiMAX®); a Bluetooth® standard; an ultra-wideband (UWB) standard (e.g., IEEE 802.15.4); and so forth. In some implementations, the wireless link 106 may provide power wirelessly, and the electronic device 102 or the base station 104 may comprise a power source.

As shown for some implementations, the electronic device 102 can include at least one application processor 108 and at least one computer-readable storage medium 110 (CRM 110). The application processor 108 may include any type of processor, such as a central processing unit (CPU) or a multi-core processor, that is configured to execute processor-executable instructions (e.g., code) stored by the CRM 110. The CRM 110 may include any suitable type of data storage media, such as volatile memory (e.g., random-access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include one or more input/output ports 116 (I/O ports 116) and at least one display 118. The I/O ports 116 enable data exchanges or interaction with other devices, networks, or users. The I/O ports 116 may include serial ports (e.g., universal serial bus (USB®) ports), parallel ports, ethernet ports, audio ports, infrared (IR) ports, cameras or other sensor ports, and so forth. The display 118 can be realized as a display screen or a projection that presents graphical images provided by other components of the electronic device 102, such as a user interface (UI) associated with an operating system, program, or application. Alternatively or additionally, the display 118 may be implemented as a display port or virtual interface through which graphical content of the electronic device 102 is communicated or presented.

The electronic device 102 further includes at least one wireless interface device 120 and at least one antenna 122. The example wireless interface device 120 provides connectivity to respective networks and peer devices via a wireless link, which may be configured similarly to or differently from the wireless link 106. The wireless interface device 120 may facilitate communication over any suitable type of wireless network, such as a wireless local area network (LAN) (WLAN), wireless personal-area-network (PAN) (WPAN), peer-to-peer (P2P) network, mesh network, cellular network, wireless wide-area-network (WAN) (WWAN), and/or navigational network (e.g., the Global Positioning System (GPS) of North America or another Satellite Positioning System (SPS) or Global Navigation Satellite System (GNSS)). In the context of the example environment 100, the electronic device 102 can communicate various data and control information bidirectionally with the base station 104 via the wireless interface device 120. The electronic device 102 may, however, communicate directly with other peer devices, an alternative wireless network, and the like. Also, as described above, an electronic device 102 may alternatively be implemented as a base station 104 or another apparatus as set forth herein.

As shown, the wireless interface device 120 can include at least one communication processor 124, at least one transceiver 126 (e.g., a wireless transceiver 126), and at least one radio-frequency front-end 128 (RFFE 128). These components process data information, control information, and signals associated with communicating information for the electronic device 102 via the antenna 122. The communication processor 124 may be implemented as at least part of a system-on-chip (SoC), as a modem processor, or as a baseband radio processor (BBP) that enables a digital communication interface for data, voice, messaging, or other applications of the electronic device 102. The communication processor 124 can include a digital signal processor (DSP) or one or more signal-processing blocks (not shown) for encoding and modulating data for transmission and for demodulating and decoding received data. Additionally, the communication processor 124 may also manage (e.g., control or configure) aspects or operation of the transceiver 126, the RF front-end 128, and other components of the wireless interface device 120 to implement various communication protocols or communication techniques.

In some cases, the application processor 108 and the communication processor 124 can be combined into one module or integrated circuit (IC), such as an SoC. Regardless, the application processor 108, the communication processor 124, or a processor generally can be operatively coupled to one or more other components, such as the CRM 110 or the display 118, to enable control of, or other interaction with, the various components of the electronic device 102. For example, at least one processor 108 or 124 can present one or more graphical images on a display screen implementation of the display 118 based on one or more wireless signals transmitted or received via the at least one antenna 122 using components of the wireless interface device 120. Further, the application processor 108 or the communication processor 124, including a combination thereof, can be realized using digital circuitry that implements logic or functionality that is described herein. Additionally, the communication processor 124 may also include or be associated with a memory (not separately depicted) to store data and processor-executable instructions (e.g., code), such as the same or another CRM 110.

As shown, the wireless interface device 120 can include at least one amplifier circuit 130 (or amplification circuit 130), which is described below. More specifically, the transceiver 126 can include at least one amplifier circuit 130-2, or the RF front-end 128 can include at least one amplifier circuit 130-1 (including both components can have at least one amplifier circuit 130 in accordance with an optional but permitted inclusive- or interpretation of the word “or”). The transceiver 126 can also include circuitry and logic for filtering, switching, amplification, channelization, frequency translation, and so forth. Frequency translation functionality may include an up-conversion or a down-conversion of frequency that is performed through a single conversion operation (e.g., with a direct-conversion architecture) or through multiple conversion operations (e.g., with a superheterodyne architecture). Generally, the transceiver 126 can include filters, switches, amplifiers, mixers, and so forth for routing and conditioning signals that are transmitted or received via the antenna 122.

In addition to the amplifier circuit 130-2, the transceiver 126 can include an analog-to-digital converter (ADC) or a digital-to-analog converter (DAC) (not shown in FIG. 1). In operation, an ADC can convert analog signals to digital signals, and a DAC can convert digital signals to analog signals. Generally, an ADC or a DAC can be implemented as part of the communication processor 124, as part of the transceiver 126, or separately from both (e.g., as another part of an SoC or as part of the application processor 108).

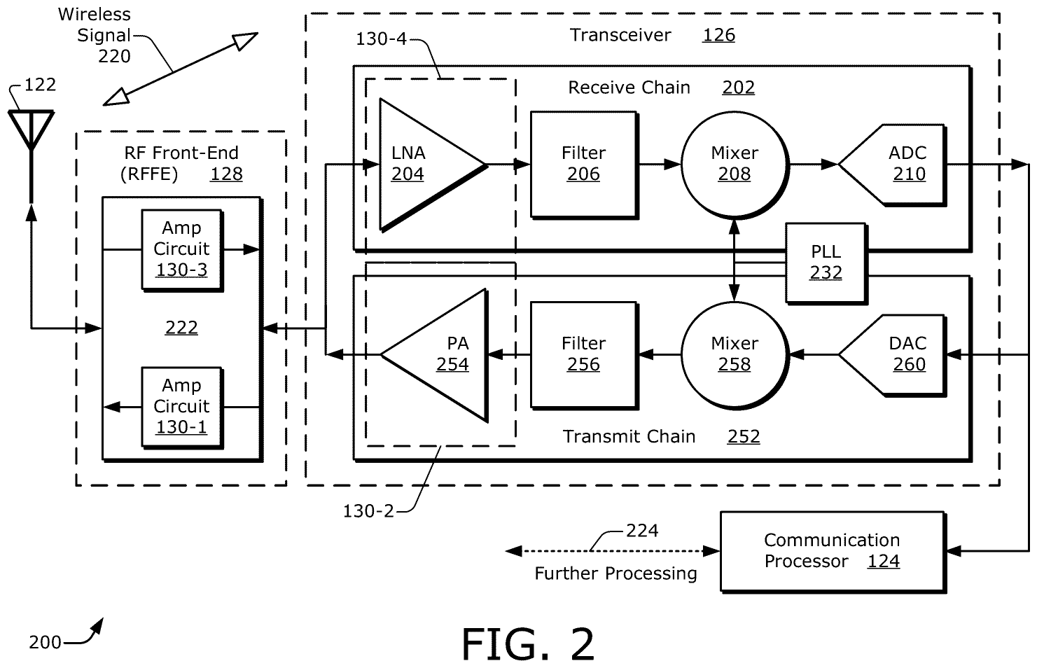

The components or circuitry of the transceiver 126 can be implemented in any suitable fashion, such as with combined transceiver logic or separately as respective transmitter and receiver entities. In some cases, the transceiver 126 is implemented with multiple or different sections to implement respective transmitting and receiving operations (e.g., with separate transmit and receive chains as depicted in FIG. 2). Although not shown in FIG. 1, the transceiver 126 may also include logic to perform in-phase/quadrature (I/Q) operations, such as synthesis, phase correction, modulation, demodulation, and the like.

The RF front-end 128 can include one or more filters, multiple switches, or one or more amplifiers—such as the amplifier circuit 130-1—for conditioning signals received via the antenna 122 or for conditioning signals to be transmitted via the antenna 122. The RF front-end 128 may also include a phase shifter (PS), peak detector, power meter, gain control block, antenna tuning circuit, n-plexer, balun, and the like. Configurable components of the RF front-end 128, such as some phase shifters, an automatic gain controller (AGC), or a switch, may be controlled by the communication processor 124 to implement communications in various modes, communications with different frequency bands and/or carrier aggregation (CA), or communications using beamforming.

In some implementations, the antenna 122 is implemented as at least one antenna array that includes multiple antenna elements. Thus, as used herein, an “antenna” can refer to at least one discrete or independent antenna, to at least one antenna array that includes multiple antenna elements, or to a portion of an antenna array (e.g., an antenna element), depending on context or implementation. At least one antenna 122 may also be part of a module that includes one or more other components (e.g., an amplifier circuit 130-1 or a filter) of the RF front-end 128, or the at least one antenna 122 may be a separate component.

In FIG. 1, an example amplifier circuit 130 is depicted as being part of a transceiver 126 as amplifier circuit 130-2, as being part of an RF front-end 128 as amplifier circuit 130-1, and so forth. Described implementations of an amplifier circuit 130 can, however, additionally or alternatively be employed in other portions of the wireless interface device 120 or in other portions of the electronic device 102 generally. As set forth above, an amplifier circuit 130 can be included in an electronic device other than a cell phone, such as a base station 104. With a base station (or a mobile phone), by way of example only, a transmit or receive chain of a transceiver 126 and/or an RF front-end 128 may include an amplifier circuit 130 as described herein. Other electronic device apparatuses that can employ an amplifier circuit 130 include a laptop, communication hardware of a vehicle, a wireless access point, and so forth as described herein.

In example implementations, the amplifier circuit 130 can include at least one port 132, such as an input port 132-1 and an output port 132-2 (or, more generally, a first port 132-1 and a second port 132-2). As illustrated, the amplifier circuit 130 can include at least one driver amplifier 134, at least one power amplifier 136, at least one clamping circuit 138, and at least one interstage matching network 140. In some cases, the driver amplifier 134 and the power amplifier 136 are coupled in series between the input port 132-1 and the output port 132-2. As shown, the driver amplifier 134 can be coupled closer to the input port 132-1 than is the power amplifier 136, and the power amplifier 136 can be coupled closer to the output port 132-2 than is the driver amplifier 134. Thus, the driver amplifier 134 can be coupled between the input port 132-1 and the power amplifier 136, and the power amplifier 136 can be coupled between the driver amplifier 134 and the output port 132-2.

Further, the driver amplifier 134, the interstage matching network 140, and the power amplifier 136 can be coupled in series between the input port 132-1 and the output port 132-2. The coupling may include an electromagnetic coupling, such as with two or more inductors that form at least one transformer, which is used as a balun to produce differential signaling. As shown, the interstage matching network 140 can be coupled between the driver amplifier 134 and the power amplifier 136 to facilitate signal propagation therebetween. The clamping circuit 138 may be coupled to the interstage matching network 140 to provide power clamping functionality for one or more parts, cells, or stages of the amplifier circuit 130 as described herein.

As depicted, signal flow can proceed from the input port 132-1 to and through the driver amplifier 134. From the driver amplifier 134, a first amplified signal can propagate to and through the interstage matching network 140 as an intermediate signal (e.g., an interstage signal). At the power amplifier 136, the first amplified signal or the intermediate signal is amplified to produce a second amplified signal. The second amplified signal is output from the power amplifier 136 and can travel to the output port 132-2. In conjunction with the interstage matching network 140, the clamping circuit 138 can clamp a power level of the intermediate signal to produce a clamped signal for protection of downstream components. In such cases, the power amplifier 136 can safely amplify the clamped signal.

Two amplifiers of the amplifier circuit 130 are described herein primarily in terms of a driver amplifier 134 and a power amplifier 136. However, two or more amplifiers that are coupled to or protected by a clamping circuit 138 may be generally referred to as a first amplifier and a second amplifier. Such other amplifiers may be or may include any type of amplifier that is employed for any purpose, such as low-noise amplifier, an operational amplifier, any given class of amplifier, a combination thereof, and so forth. The first and second amplifiers may be coupled together by an interstage matching network 140.

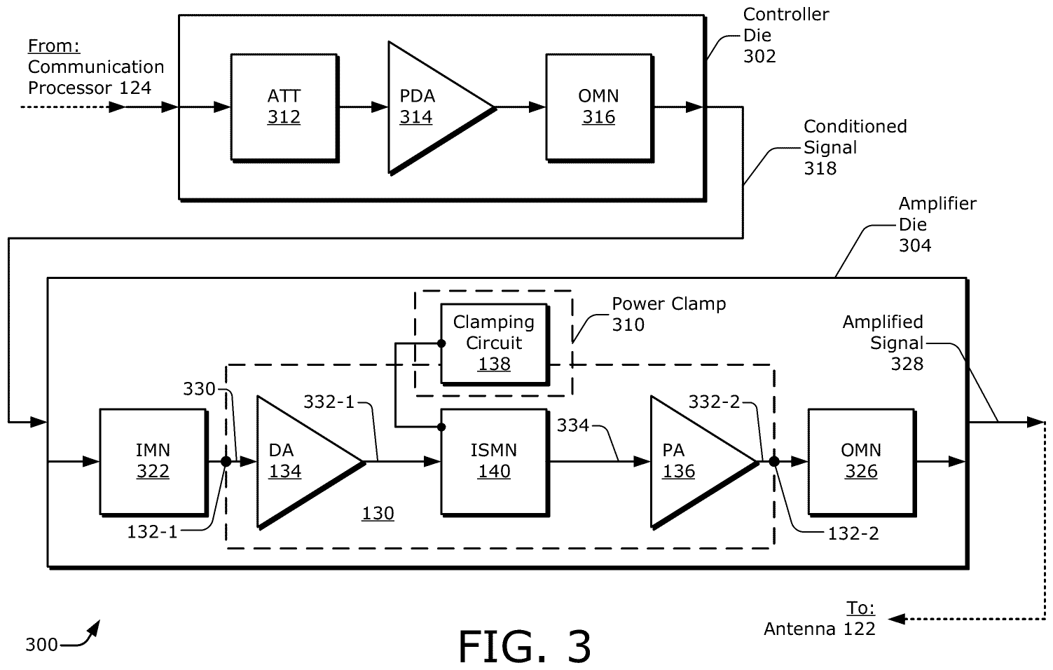

Although a particular quantity and arrangement of components are explicitly depicted in FIG. 1 (and in FIGS. 2 to 6-2), the illustrated circuitry, including an amplifier circuit 130, may include more or fewer of any of such components, as well as include other components that are not shown. Further, the components may be arranged and interconnected in different manners. Example implementations of a clamping circuit 138 and at least one node to which it is coupled are described below with reference to multiple figures, starting with FIGS. 3, 4, and 5. Next, however, this document describes example implementations of a transceiver and an RF front-end with reference to FIG. 2.

FIG. 2 is a schematic diagram 200 illustrating an example RF front-end 128 and an example transceiver 126 that can each include at least one amplifier circuit 130 with a clamping circuit 138 (not shown in FIG. 2). FIG. 2 also depicts an antenna 122 and a communication processor 124. The communication processor 124 communicates one or more data signals to other components, such as the application processor 108 of FIG. 1, for further processing at 224 (e.g., for processing at an application level). As shown, the circuitry 200 can include a first amplifier circuit 130-1, a second amplifier circuit 130-2, a third amplifier circuit 130-3, or a fourth amplifier circuit 130-4, including one to four of such amplifier circuits. The circuitry 200, however, may include a different quantity of amplifiers (e.g., more or fewer amplifier circuits), may include amplifiers or other components that are coupled together differently, may include amplifiers in different locations, may include amplifiers that are implemented with two or more stages, some combination thereof, and so forth.

As illustrated from left to right, in example implementations, the antenna 122 is coupled to the RF front-end 128, and the RF front-end 128 is coupled to the transceiver 126. The transceiver 126 is coupled to the communication processor 124. The example RF front-end 128 includes at least one signal propagation path 222. The at least one signal propagation path 222 can include at least one amplifier circuit 130, such as the amplifier circuit 130-1 and the amplifier circuit 130-3. The example wireless transceiver 126 includes at least one receive chain 202 (or receive path 202) and at least one transmit chain 252 (or transmit path 252). Although only one RF front-end 128, one transceiver 126, and one communication processor 124 are shown at the circuitry 200, an electronic device 102, or a wireless interface device 120 thereof, can include multiple instances of any or all such components. Also, although only certain components are explicitly depicted in FIG. 2 and are shown coupled together in a particular manner, the transceiver 126 or the RF front-end 128 may include other non-illustrated components (e.g., switches or buffers), more or fewer components, differently coupled arrangements of components, and so forth.

In some implementations, the RF front-end 128 couples the antenna 122 to the transceiver 126 via the signal propagation path 222. In operation, the signal propagation path 222 carries a signal between the antenna 122 and the transceiver 126. During or as part of the signal propagation, the signal propagation path 222 conditions the propagating signal, such as with the amplifier circuit 130-1 or the amplifier circuit 130-3. This enables the RF front-end 128 to couple a wireless signal 220 from the antenna 122 to the transceiver 126 as part of a reception operation. The RF front-end 128 also enables a transmission signal to be coupled from the transceiver 126 to the antenna 122 as part of a transmission operation to emanate a wireless signal 220. Although not explicitly shown in FIG. 2, an RF front-end 128, or a signal propagation path 222 thereof, may include one or more other components, such as an amplifier or another amplifier circuit (e.g., a driver amplifier, a power amplifier, or a low-noise amplifier), a filter, an n-plexer, a phase shifter, a diplexer, one or more switches, and so forth.

In some implementations, the transceiver 126 can include at least one receive chain 202, at least one transmit chain 252, or at least one receive chain 202 and at least one transmit chain 252. From left to right, the receive chain 202 can include a low-noise amplifier 204 (LNA 204), a filter 206, a mixer 208 for frequency down conversion, and an ADC 210. The transmit chain 252 can include a power amplifier 254 (PA 254), a filter 256, a mixer 258 for frequency up-conversion, and a DAC 260. However, the receive chain 202 or the transmit chain 252 can include other components—for example, additional amplifiers or filters (e.g., a baseband-frequency, intermediate-frequency, or radio-frequency filter), multiple mixers, one or more buffers, or at least one local oscillator—that are electrically or electromagnetically disposed anywhere along the depicted receive and transmit chains.

The receive chain 202 is coupled between the signal propagation path 222 of the RF front-end 128 and the communication processor 124—e.g., via the low-noise amplifier 204 and the ADC 210, respectively. The transmit chain 252 is coupled between the signal propagation path 222 and the communication processor 124—e.g., via the power amplifier 254 and the DAC 260, respectively. The transceiver 126 can also include at least one phase-locked loop 232 (PLL 232) that is coupled to the mixer 208 or the mixer 258. For example, the transceiver 126 can include one PLL 232 for each transmit/receive chain pair, one PLL 232 per transmit chain and one PLL 232 per receive chain, multiple PLLs 232 per chain, and so forth.

As shown along a signal propagation direction for certain example implementations of the receive chain 202, the antenna 122 is coupled to the low noise amplifier 204 via the signal propagation path 222 and the amplifier circuit 130-3 thereof. The low-noise amplifier 204 is coupled to the filter 206. The filter 206 is coupled to the mixer 208, and the mixer 208 is coupled to the ADC 210. The ADC 210 is in turn coupled to the communication processor 124. As shown along a signal propagation direction for certain example implementations of the transmit chain 252, the communication processor 124 is coupled to the DAC 260, and the DAC 260 is coupled to the mixer 258. The mixer 258 is coupled to the filter 256, and the filter 256 is coupled to the power amplifier 254. The power amplifier 254 is coupled to the antenna 122 via the signal propagation path 222 using the amplifier circuit 130-1 thereof. Although only one receive chain 202 and one transmit chain 252 are explicitly shown, an electronic device 102, or a transceiver 126 thereof, can include multiple instances of either or both components. Although the ADC 210 and the DAC 260 are illustrated as being separately coupled to the communication processor 124, they may share a bus or other mechanism for communicating with the processor 124. Further, the ADC 210 or the DAC 260 may be part of the communication processor 124 instead of the transceiver 126 as illustrated or separate from the transceiver 126 and the communication processor 124.

As part of an example signal-receiving operation, the amplifier circuit 130-3 of the signal propagation path 222 amplifies a received signal and forwards the amplified signal to the low-noise amplifier 204. The low-noise amplifier 204 accepts the amplified signal from the RF front-end 128 and provides another amplified signal to the filter 206 based on the accepted signal. The filter 206 filters the other amplified signal and provides a filtered signal to the mixer 208. The mixer 208 performs a frequency conversion operation on the filtered signal to down-convert from one frequency to a lower frequency (e.g., from a radio frequency (RF) to an intermediate frequency (IF) or from RF or IF to a baseband frequency (BBF)). The mixer 208 can perform the frequency down-conversion in a single conversion step or through multiple conversion steps using at least one PLL 232. The mixer 208 can provide a down-converted signal to the ADC 210 for conversion and forwarding to the communication processor 124 as a digital signal.

As part of an example signal-transmitting operation, the mixer 258 accepts an analog signal at BBF from the DAC 260 (or accepts an analog IF signal if the signal has already been upconverted once by another mixer (not shown)). The mixer 258 upconverts the analog signal to a higher frequency, such as to an RF frequency, to produce an RF signal using a signal generated by the PLL 232 to have a target synthesized frequency. The mixer 258 provides the RF or other upconverted signal to the filter 256. The filter 256 filters the RF signal and provides a filtered signal to the power amplifier 254. Thus, after the filtering by the filter 256, the power amplifier 254 amplifies the filtered signal and provides an amplified signal to the signal propagation path 222 for signal conditioning. The RF front-end 128 can use, for instance, the amplifier circuit 130-1 of the signal propagation path 222 to provide a further amplified signal to the antenna 122 for emanation as a wireless signal 220.

Example implementations of an amplifier circuit 130, as described herein, may be employed at any one or more of the example amplifier circuits 130-1, 130-2, 130-3, or 130-4 in the transceiver 126 or the RF front-end 128 or at other signal amplification locations of an electronic device 102 (not shown in FIG. 2). In some cases, if the first amplifier circuit 130-1 of the RF front-end 128 includes a driver amplifier 134, a power amplifier 136, an interstage matching network 140, and a clamping circuit 138 (e.g., of FIGS. 1 and 3), the transceiver 126 may omit a power amplifier 254 or an amplifier circuit 130-2, or the transceiver 126 may “substitute” a driver amplifier or a pre-driver amplifier therefor. Additionally or alternatively, the second amplifier circuit 130-2 may include a driver amplifier, a clamping circuit 138, and an interstage matching network 140 (none of which are explicitly shown in FIG. 2) in conjunction with the depicted power amplifier 254 (e.g., as part of the second amplifier circuit 130-2).

In some cases, the third amplifier circuit 130-3 of the RF front-end 128 includes two or more amplifiers in conjunction with an interstage matching network 140 and a clamping circuit 138 (e.g., as shown in FIGS. 1 and 3). At least one of these two or more amplifiers may be realized as a low-noise amplifier for receive signal processing. Additionally or alternatively, the fourth amplifier circuit 130-4 may include a driver amplifier, an interstage matching network 140, and a clamping circuit 138 (none of which are explicitly shown in FIG. 2) in conjunction with the depicted low-noise amplifier 204 (e.g., as part of the fourth amplifier circuit 130-4). Further, the fourth amplifier circuit 130-4 may instead include multiple low-noise amplifiers in conjunction with an interstage matching network 140 and a clamping circuit 138 that provides a clamping function for a propagating signal. Generally, an amplifier circuit 130 with a clamping circuit 138 can be deployed anywhere in a transceiver 126, an RF front-end 128, another portion of a wireless interface device 120, or another part of an electronic device 102 to protect an input of any type of amplifier.

The circuitry 200, however, depicts just some examples for a transceiver 126 and/or an RF front-end 128. In some cases, the various components that are illustrated in the drawings using separate schematic blocks or circuit elements may be manufactured or packaged in different discrete manners. For example, one physical module may include components of the RF front-end 128 and a portion of the components of the transceiver 126, and another physical module may combine the communication processor 124 with the remaining components of the transceiver 126. Further, in some cases, the antenna 122 may be co-packaged with at least some components of the RF front-end 128 (e.g., may be co-packaged with an amplifier circuit 130 and at least one filter) or with those of the transceiver 126. Although certain amplifiers in FIG. 2 are depicted as an amplifier circuit 130 that can include a clamping circuit 138 (not shown in FIG. 2) that clamps power in conjunction with an interstage matching network 140 as described herein, any one or more of such amplifier circuits may instead be implemented without a clamping circuit 138 or as an amplifier circuit that clamps a voltage or a current in a different manner.

In additional or alternative implementations, one or more components may be physically or logically “shifted” to a different part of the wireless interface device 120 as compared to the illustrated circuitry 200 and/or may be incorporated into a different module. For example, a low-noise amplifier 204 or a power amplifier 254 may alternatively or additionally be deployed in the RF front-end 128, such as by being at least part of the amplifier circuit 130-3 or the amplifier circuit 130-1, respectively. Examples of an amplifier circuit 130-1 or 130-2 with a power amplifier 136 (or a power amplifier 254) are described next with reference to FIG. 3. In some cases, a power amplifier 136 may be implemented with or using a power amplifier 254.

FIG. 3 is a schematic diagram 300 illustrating an example amplifier die 304 including an amplifier circuit 130, which has an interstage matching network 140 coupled between a driver amplifier 134 and a power amplifier 136, and a clamping circuit 138 coupled to the interstage matching network 140. As illustrated, the schematic diagram 300 includes a controller die 302 and the amplifier die 304. The controller die 302 and the amplifier die 304 can be coupled together in series between a communication processor 124 (e.g., of FIGS. 1 and 2) and an antenna 122 (e.g., of FIGS. 1 and 2). More generally, two separate integrated circuit dies or chips may be referred to as a first die and a second die.

In example operations, an input of the controller die 302 receives a signal from the communication processor 124. Although not shown in FIG. 3, other components (e.g., a mixer, a filter, or a DAC) may be coupled between the communication processor 124 and the input of the controller die 302. The controller die 302 can produce a conditioned signal 318 as part of a signal-control process. An output of the controller die 302 provides the conditioned signal 318, and the conditioned signal 318 is coupled to an input of the amplifier die 304. Although not shown, there may be one or more components coupled between the output of the controller die 302 and the input of the amplifier die 304.

The amplifier die 304, which includes at least one amplifier, amplifies the conditioned signal 318 to produce an amplified signal 328. After amplification, the amplifier die 304 provides the amplified signal 328 at an output of the amplifier die 304. The amplified signal 328 can be forwarded to the antenna 122. Although not shown in FIG. 3, other components (e.g., a mode switch, a filter, another amplifier, or a front-end module (FEM)) can be coupled between the output of the amplifier die 304 and the antenna 122.

As shown, the controller die 302 includes at least one attenuator 312 (ATT 312), at least one pre-driver amplifier 314 (PDA 314), and at least one output-matching network 316 (OMN 316). The attenuator 312, the pre-driver amplifier 314, and the output-matching network 316 are coupled together in series between the input and the output of the controller die 302. The controller die 302 may, however, include more, fewer, or different components. Further, the depicted components and other components may be arranged or coupled together similarly or differently from how those that are depicted are arranged and coupled together.

In one approach (not shown), a power clamp can be coupled between the attenuator 312 and the pre-driver amplifier 314. Such a power clamp can limit the power that is input to downstream components, such as the power amplifier 136. However, as described above, the relatively long signal path between the pre-driver amplifier 314 of the controller die 302 and the power amplifier 136 of the amplifier die 304 creates signaling problems. These problems include signal degradation and a failure to attain a targeted power clamping protection threshold at the power amplifier 136.

In example implementations, to ameliorate these problems at least partly, this document describes incorporating at the interstage matching network 140 on the amplifier die 304 at least one clamping circuit 138 as at least part of at least one power clamp 310. The clamping circuit 138 can provide power clamping for an integrated circuit die with respect to, for instance, the power of a signal that is supplied to an input of the power amplifier 136. In addition to the amplifier circuit 130, the amplifier die 304 can include an input-matching network 322 (IMN 322) and an output-matching network 326 (OMN 326). The input-matching network 322, the amplifier circuit 130, and the output-matching network 326 can be coupled together in series between the input and the output of the amplifier die 304.

As shown, the input-matching network 322 may be coupled between the input of the amplifier die 304 and the amplifier circuit 130 (e.g., via the input port 132-1 of the amplifier circuit 130). The output-matching network 326 may be coupled between the amplifier circuit 130 (e.g., via the output port 132-2 of the amplifier circuit 130) and the output of the amplifier die 304. The amplifier circuit 130 may be coupled between the input-matching network 322 and the output-matching network 326 in a series connection between the input and the output of the amplifier die 304. The amplifier die 304 may, however, include more, fewer, or different components. Further, the depicted components and other components may be arranged or coupled together similarly or differently as compared to how the depicted ones are arranged and coupled together.

As illustrated, the amplifier circuit 130 includes the at least one driver amplifier 134 (DA 134), the at least one power amplifier 136 (PA 136), and the at least one interstage matching network 140 (ISMN 140). The driver amplifier 134 includes a driver amplifier input and a driver amplifier output. The power amplifier 136 includes a power amplifier input and a power amplifier output. In some cases, the driver amplifier 134, the interstage matching network 140, and the power amplifier 136 are coupled together in series between the input port 132-1 and the output port 132-2 of the amplifier circuit 130. As shown, the driver amplifier 134 can be coupled closer to the input port 132-1 than is the power amplifier 136, and the power amplifier 136 can be coupled closer to the output port 132-2 than is the driver amplifier 134. Thus, the driver amplifier 134 can be coupled between the input port 132-1 and the power amplifier 136, and the power amplifier 136 can be coupled between the driver amplifier 134 and the output port 132-2.

The interstage matching network 140 can be coupled between two stages—e.g., a first stage corresponding to the driver amplifier 134 and a second stage corresponding to the power amplifier 136. Accordingly, the driver amplifier 134 can be coupled between the input port 132-1 of the amplifier circuit 130 via the driver amplifier input and the interstage matching network 140 via the driver amplifier output. The power amplifier 136 can be coupled between the interstage matching network 140 via the power amplifier input and the output port 132-2 of the amplifier circuit 130 via the power amplifier output.

The clamping circuit 138 may be coupled to the interstage matching network 140 to provide power clamping functionality for one or more parts, cells, stages, or components of the amplifier die 304, including of the amplifier circuit 130. For instance, as at least part of the power clamp 310, the clamping circuit 138 can provide power protection for downstream components, including for an input of the power amplifier 136. The clamping circuit 138 can be coupled, for example, to a wire, trace, or other electrical path between the driver amplifier 134 and the power amplifier 136; to a node that is coupled between two or more components (e.g., between a capacitor and an inductor or between two capacitors) of the interstage matching network 140; to a node or electrical path that propagates a signal from an output of the driver amplifier 134 to an input of the power amplifier 136; some combination thereof; and so forth. Example couplings between the clamping circuit 138 and the interstage matching network 140 are described below with reference to FIGS. 4 to 6-2.

As depicted, signal flow can proceed from the input port 132-1 to the driver amplifier 134 as a signal 330. The signal 330 can be realized as an input signal, a conditioned signal, a pre-amplified signal, a combination thereof, and so forth. The driver amplifier 134 produces a first amplified signal 332-1 based on amplifying the signal 330. From the driver amplifier 134, the first amplified signal 332-1 can propagate through the interstage matching network 140 as an intermediate signal 334 (e.g., as an interstage signal 334). The interstage matching network 140 can couple the intermediate signal 334 to an input of the power amplifier 136, which produces a second amplified signal 332-2 based on the intermediate signal 334. The second amplified signal 332-2, which is output from the power amplifier 136, can travel to the output port 132-2 of the amplifier circuit 130 and then to the output-matching network 326. The output-matching network 326 can couple the second amplified signal 332-2 to the output of the amplifier die 304 as the amplified signal 328.

Signals, such as the conditioned signal 318, the signal 330, the first amplified signal 332-1, the intermediate signal 334, the second amplified signal 332-2, or the amplified signal 328, may be different signals in terms of average power, frequency, phase, position or location in a circuit, singled-ended versus differential, a combination thereof, and so forth. One or more of these signals may, however, constitute a same signal in terms of being a transmission signal propagating toward an antenna along a transmission chain, of having a same modulation, of carrying the same information in the signal, a combination thereof, and so forth.

The clamping circuit 138 is illustrated in FIG. 3 as being coupled to a left side of the interstage matching network 140 for clarity. As depicted in FIG. 3, the left side of the interstage matching network 140 is nearer an input of the interstage matching network 140 than an output thereof. Nonetheless, a clamping circuit 138 can be coupled to any portion of, or to any of one or more nodes of, the interstage matching network 140. Such a portion or node(s) may instead be nearer the power amplifier 136 or at least proximate to a central part of the interstage matching network 140, just to name a couple of examples.

Two amplifiers of the amplifier circuit 130 are described herein primarily in terms of a driver amplifier 134 and a power amplifier 136. However, two or more amplifiers, which include at least one amplifier that is protected by a clamping circuit 138, may be generally referred to as first amplifier and a second amplifier. Such other amplifiers may be or may include any type of amplifier that is employed for any purpose, such as low-noise amplifier, an operational amplifier, an amplifier of any given class, a combination thereof, and so forth.

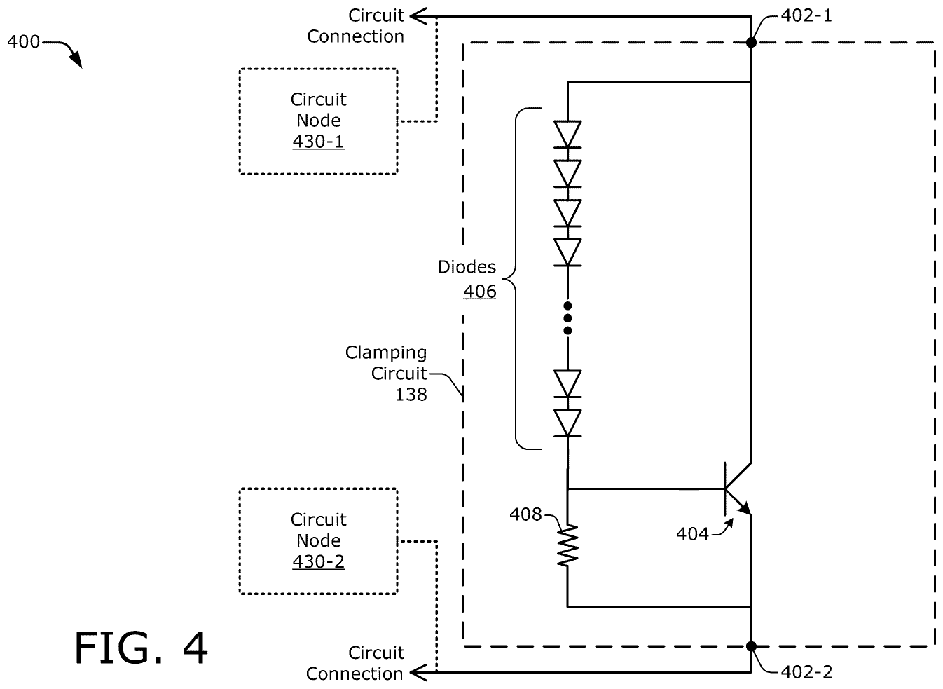

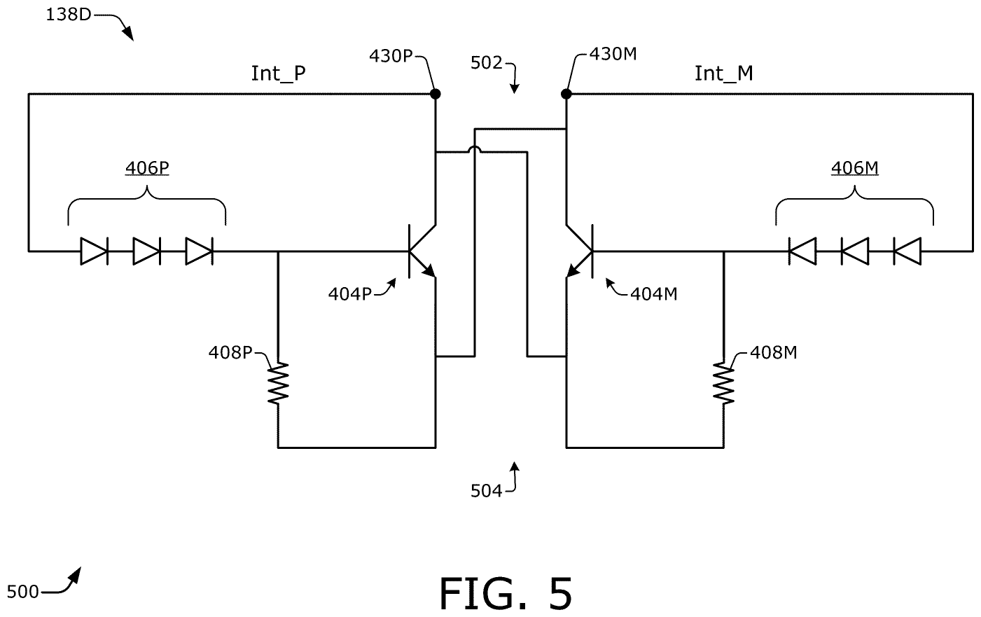

FIG. 4 is a circuit diagram 400 illustrating an example clamping circuit 138, which may be coupled to an interstage matching network 140 of an amplifier circuit 130 (e.g., of FIGS. 1, 3, 6-1, and 6-2) to provide power clamping in single-ended or differential implementations. The clamping circuit 138 includes at least two nodes that can be used to couple the clamping circuit 138 to a larger circuit, such as via an interstage matching network 140. These at least two nodes include a first node 402-1 and a second node 402-2. Example circuit connections are described below with reference to FIGS. 4 and 5 and further with reference to FIGS. 6-1 and 6-2.

In example implementations, the clamping circuit 138 includes at least one transistor 404 that is coupled between the first node 402-1 and the second node 402-2. For instance, a channel terminal (e.g., a first channel terminal) of the transistor 404 may be coupled to the first node 402-1. Further, another channel terminal (e.g., a second channel terminal) of the transistor 404 may be coupled to the second node 402-2. A control terminal of the transistor 404 may be coupled to other components of the clamping circuit 138 as described below.

Multiple transistors are described herein and depicted in the associated figures, which figures are incorporated by reference herein. These transistors may be realized in different manners or as different transistor types. Example transistor types include a field effect transistor (FET), a junction FET (JFET), a metal-oxide-semiconductor FET (MOSFET), a bipolar junction transistor (BJT), an insulated-gate bipolar transistor (IGBT), a heterojunction bipolar transistor (HBT), a combination thereof, and so forth. Manufacturers may fabricate FETs as n-channel or p-channel transistor types and may fabricate BJTs as NPN or PNP transistor types. The heterojunction bipolar transistor (HBT) type, for instance, can be considered a form or subset of the bipolar junction transistor (BJT) type. Although certain transistors are depicted in the figures as HBTs, one or more of these transistors may be implemented as a different transistor type, such as another type of BJT, an FET, and so forth.

Each transistor may include at least one control terminal and one or more channel terminals. With an FET, a control terminal can correspond to a gate terminal, and a channel terminal can correspond to a source terminal or a drain terminal. With a BJT (including an HBT), a control terminal can correspond to a base terminal, and a channel terminal can correspond to an emitter terminal or a collector terminal. In some circuit configurations, a source terminal of an FET can be analogous to an emitter terminal of a BJT. Similarly, a drain terminal of an FET can be analogous to a collector terminal of a BJT.

With continuing reference to FIG. 4, in the depicted example clamping circuit 138, a collector terminal of the transistor 404 is coupled to the first node 402-1. An emitter terminal of the transistor 404 is coupled to the second node 402-2. A base terminal of the transistor 404 is coupled to other components of the clamping circuit 138, as is described next. However, the transistor 404 may be coupled to the first and second nodes 402-1 and 402-2 or to the other depicted components of the clamping circuit 138 in alternative manners.

As illustrated, two or more diodes 406 can be coupled together in series between the first node 402-1 and the base terminal (or gate terminal) of the transistor 404. A quantity of diodes of these two or more diodes 406 can set, at least in part, a voltage level that triggers protection by the clamping circuit 138. For example, a voltage drop that turns on each diode, which can be dependent on material or process technology, multiplied by the quantity of diodes may establish a voltage level to turn on the at least one transistor 404 of the clamping circuit 138. Thus, a power clamp 310 (e.g., of FIG. 3) that is implemented using a clamping circuit 138 as described herein can be designed to provide protection at different power level thresholds. This may be achieved, at least in part, by deploying different quantities of triggering diodes for the two or more diodes 406 to establish a clamping voltage that is implemented by the clamping circuit 138.

At least one resistor 408 is shown coupled between the base terminal (or gate terminal) of the transistor 404 and the second node 402-2. Generally, the resistor 408 can be coupled between two terminals of the transistor 404. More specifically, the resistor 408 can be coupled between a control terminal of the transistor 404 and a channel terminal of the transistor 404. For example, if the transistor 404 is realized as a bipolar junction transistor (BJT) (e.g., a heterojunction bipolar transistor (HBT)), the control terminal of the transistor 404 can comprise a base terminal of the bipolar junction transistor, and the channel terminal of the transistor 404 can comprise an emitter terminal of the bipolar junction transistor. A resistor can include two terminals: a first terminal and a second terminal. As illustrated in FIG. 4, the first terminal of the resistor 408 can be coupled to a first terminal of the transistor 404, and the second terminal of the resistor 408 can be coupled to a second terminal of the transistor 404.

A resistive value of the resistor 408 can also set, at least partly, a trigger voltage at which clamping protection starts. Generally, as the resistive value of the resistor 408 increases, the trigger voltage at which clamping is initiated decreases. Further, the resistor 408 can facilitate a greater clamping balance between plus and minus circuit components of a differential amplifier circuit and between positive and negative differential signaling responsive to the clamping circuit 138 being deployed in a differential implementation. An example differential implementation of the clamping circuit 138 is described below with reference to FIG. 5.

The components that are depicted as being part of the clamping circuit 138 in FIG. 4, besides the at least one transistor 404, may be omitted from the clamping circuit 138 or may be coupled to the at least one transistor 404 while being separate from the clamping circuit 138. Further, certain components are depicted or described as having a particular quantity, such as singular, plural, multiple, one, two, three, and so forth. Each of these components may, however, have a different quantity. By way of example only, the series-connected string of diodes 406 may instead be implemented with a single diode 406.

In example implementations, the clamping circuit 138 can, for instance, be coupled to or incorporated into an amplifier circuit 130 in different manners and to different nodes of a circuit, as described herein. To couple the clamping circuit 138 to a circuit, the first node 402-1 may be connected to one node of the amplifier circuit 130—such as to a first circuit node 430-1, and the second node 402-2 may be connected to another node of the circuit—such as to a second circuit node 430-2.

To clamp a signal from a forward-swing perspective, the first node 402-1 can be coupled to a node of the interstage matching network. The interstage matching network node may be part of an interstage matching network 140 (e.g., of FIGS. 1, 3, 6-1, and 6-2). The second node 402-2 can be coupled to a power distribution node. A power distribution node can be realized with, for example, a supply voltage node (e.g., of a power rail) or a ground node (e.g., of a ground plane). With an NPN BJT (or an n-channel FET) for the transistor 404, for instance, the power distribution node can be realized with a ground node (not shown in FIG. 4). Two example power distribution node types (e.g., a supply voltage node versus a ground node) may, however, be swapped, such as if the transistor or diode dopings are swapped (e.g., PNP for NPN or p-channel for n-channel) or if the directions in which the depicted components are coupled are swapped relative to voltage potentials.

Thus, to protect against forward signal swings, the first circuit node 430-1 can correspond to a node of the interstage matching network 140, or a node that is otherwise coupled between an output of the driver amplifier 134 and an input of the power amplifier 136. The second circuit node 430-2 can correspond to a power distribution node of the circuit. The clamping circuit 138 can, however, also be used to protect against reverse signal swings, e.g., by “flipping” how the first and second nodes 402-1 and 402-2 are coupled to the amplifier circuit 130. To do so, the first node 402-1 of the clamping circuit 138 can be coupled to a power distribution node, and the second node 402-2 can be coupled to an interstage matching network node. Accordingly, to clamp a signal from a reverse-swing perspective, the first circuit node 430-1 can correspond to a power distribution node of the circuit. The second circuit node 430-2 can correspond to a node of the interstage matching network 140, or a node that is otherwise coupled between an output of the driver amplifier 134 and an input of the power amplifier 136.

The clamping circuit 138 can therefore be used to protect against forward and reverse signal swings with appropriate coupling to a circuit, such as an amplifier circuit 130. In a single-ended environment, the node of the interstage matching network 140 to which a pair of clamping circuits are coupled may be a same node. Each clamping circuit 138, however, can be coupled to this same node via a different node 402 to enable protection against forward and reverse signal swings. One is coupled via the first node 402-1, and the other is coupled via the second node 402-2. Similarly, the power distribution node to which a pair of clamping circuits is coupled may also be the same power distribution node, and the respective node 402 of each clamping circuit 138 that is coupled to the same power distribution node for each is likewise different.

In example operations, the forward-swing clamping circuit configuration can clamp “positive” voltage levels of the intermediate signal 334 (e.g., of FIG. 3) at the interstage matching network node. The reverse-swing clamping circuit configuration can clamp “negative” voltage levels of the intermediate signal 334 at the interstage matching network node. Accordingly, an input of a downstream amplifier, such as the power amplifier 136, can be protected from voltage or current levels that may be damaging to components, such as one or more parts of a transistor of the power amplifier 136. The clamping circuits can clamp a forward or a reverse voltage swing at the interstage matching network node responsive to a voltage level that is based, at least partly, on a quantity of diodes of multiple diodes 406 of the respective clamping circuit 138 (e.g., as shown in FIG. 4). Additionally or alternatively, the clamping circuit 138 can increase a clamping action on a voltage at the interstage matching network node as the voltage at the node increases.

Example instances of amplification circuitry, including an example interstage matching network 140 having multiple nodes to which a clamping circuit 138 may be coupled, are described below with reference to FIGS. 6-1 and 6-2. Next, however, a differential configuration for a clamping circuit 138 is described with reference to FIG. 5.

FIG. 5 is a circuit diagram 500 illustrating an example differential clamping circuit 138D, which may be coupled to an interstage matching network 140 of an amplifier circuit 130 to provide power clamping. In example implementations, the differential clamping circuit 138D can include a plus version and a minus version of the clamping circuit 138 (e.g., of FIG. 4). As shown, the differential clamping circuit 138D includes a plus transistor 404P and a minus transistor 404M. The differential clamping circuit 138D also includes a plus set of diodes 406P and a minus set of diodes 406M. The differential clamping circuit 138D further includes a plus resistor 408P and a minus resistor 408M.

As illustrated in FIG. 5, a differential clamping circuit 138D can be coupled to a plus intermediate node Int_P, such as a plus node of an interstage matching network 140 (e.g., of FIGS. 1, 3, 6-1, and 6-2), or a plus interstage matching network node 430P of a differential interstage matching network 140 (e.g., of FIGS. 6-1 and 6-2). Similarly, the differential clamping circuit 138D can be coupled to a minus intermediate node Int_M, such as minus node of an interstage matching network 140, or a minus interstage matching network node 430M of a differential interstage matching network 140 (e.g., of FIGS. 6-1 and 6-2). The plus transistor 404P and the minus transistor 404M can be cross coupled to each other as indicated at 502. For example, an emitter terminal (or source terminal) of the plus transistor 404P can be coupled to a collector terminal (or drain terminal) of the minus transistor 404M at the minus interstage matching network node 430M. Similarly, an emitter terminal (or source terminal) of the minus transistor 404M can be coupled to a collector terminal (or drain terminal) of the plus transistor 404P at the plus interstage matching network node 430P.

The emitter terminals (or source terminals) of the plus and minus transistors 404P and 404M need not be coupled to a ground node or another power distribution node as indicated at 504. Similarly, the plus and minus resistors 408P and 408M need not be coupled to a ground node or another power distribution node as also indicated at 504. Instead, the emitter terminals (or source terminals) of the plus and minus transistors 404P and 404M are coupled respectively to the plus and minus resistors 408P and 408M as indicated at 504.

In some cases, each resistor 408 is coupled between two terminals of a respective transistor 404. For instance, each respective resistor 408 can be coupled between a channel terminal (e.g., an emitter terminal for a BJT (or a source terminal for an FET)) and a control terminal (e.g., a base terminal for an HBT (or a gate terminal for an FET)) of a corresponding transistor 404. As shown by way of example only, the plus resistor 408P is coupled between the base terminal and the emitter terminal of the plus transistor 404P, and the minus resistor 408M is coupled between the base terminal and the emitter terminal of the minus transistor 404M. Each resistor 408 may be coupled to a control terminal of the respective transistor 404 via a node that is coupled between the control terminal of the respective transistor 404 and the series-connected two or more diodes 406.

The differential configuration of FIG. 5 enables, at least in part, each “half” of the differential clamping circuit 138D to have available trigger voltages that differ by 0.6V (e.g., for GaAs technology). For instance, in one example circuit design, with three diodes in the set of diodes 406, the “left half” (as depicted in FIG. 5) of the differential clamping circuit 138D triggers at 2.4 volts, but the “right half” of the differential clamping circuit 138D triggers at 3.0 volts. By appropriately designing the two halves of the differential clamping circuit 138D using two trigger voltages that differ by 0.6 volts, a 0.3 volt step-size for power-clamp triggering can be implemented. This enables a finer control over the trigger voltage to meet a given design specification. Implementing two clamping circuits 138 as shown in FIG. 4 (e.g., for forward and reverse signal swings), can similarly reduce trigger voltage step-size granularity.

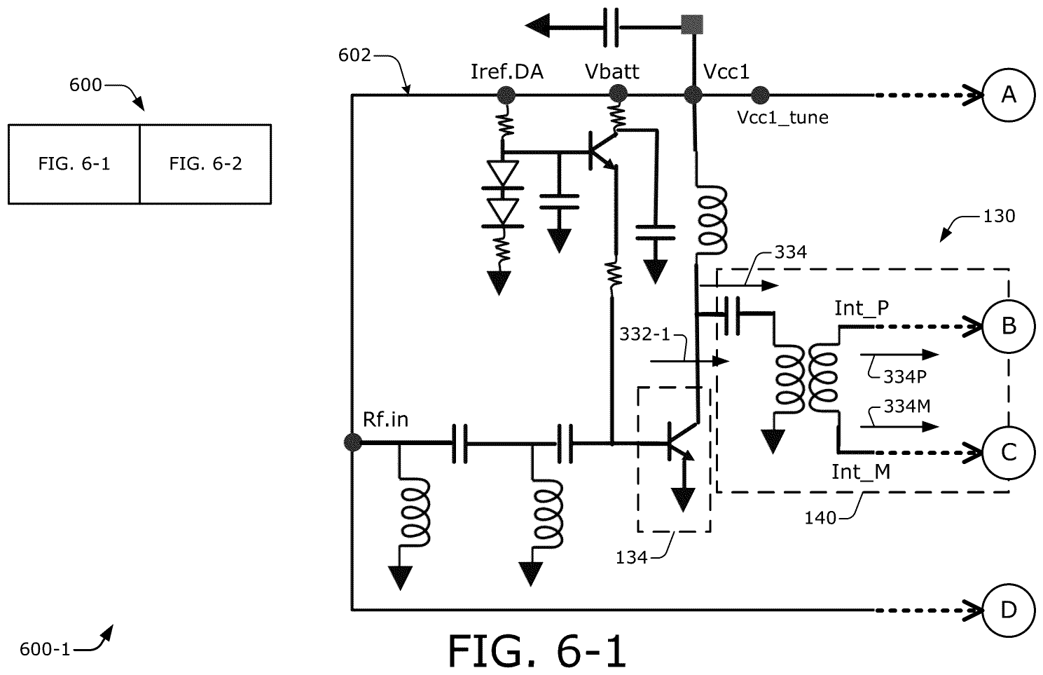

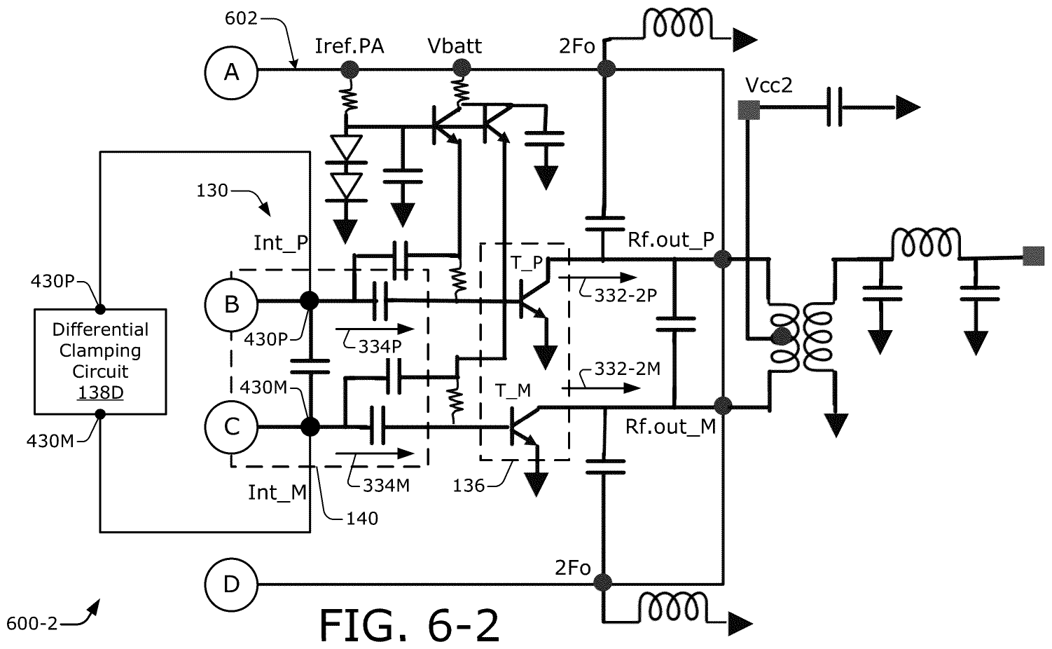

FIGS. 6-1 and 6-2 jointly depict a diagram 600 illustrating an example differential amplifier circuit 130 with a driver amplifier 134, an interstage matching network 140, and a power amplifier 136. The example differential amplifier circuit 130 also includes multiple example nodes at which a differential clamping circuit 138D (e.g., of FIG. 5) can be coupled to provide power clamping. As indicated at the block diagram 600 (at the top-left corner of FIG. 6-1), FIG. 6-1 depicts a “left” portion of the circuit as a circuit 600-1, and FIG. 6-2 depicts a “right” portion of the circuit as a circuit 600-2. The encircled letters “A,” “B,” “C,” and “D” indicate four electrical connection points between the circuit portions of FIGS. 6-1 and 6-2. FIGS. 6-1 and 6-2 jointly depict an integrated circuit die 602 that includes multiple inputs or outputs that may be realized with a pin, pad, or other electrical contact node to couple signaling to or from the integrated circuit die 602. Examples of such inputs and outputs that are depicted in FIGS. 6-1 and 6-2 include Rf.in, Int_P, Int_M, Rf.out_P, RF.out_M, Vcc1, Vcc2, and so forth.

In example implementations, the driver amplifier 134 can be single-ended and produce a first amplified signal 332-1 that is singled-ended. The interstage matching network 140 converts the single-ended amplified signal 332-1, or single-ended portion of the intermediate signal 334, into a differential intermediate signal 334. The differential intermediate signal 334 includes a plus intermediate signal 334P and a minus intermediate signal 334M. The interstage matching network 140 can include a balun, such as a transformer, to perform the signal conversion from being single ended to being differential.

In example implementations, the interstage matching network 140 can be realized with a T-network. As shown across FIGS. 6-1 and 6-2, the T-network of the interstage matching network 140 includes a first capacitor coupled between the driver amplifier output and the power amplifier input and a second capacitor also coupled between the driver amplifier output and the power amplifier input. Along one combination electrical and electromagnetic path, the first capacitor is coupled in series with the second capacitor between an output of the driver amplifier 134 and an input of the power amplifier 136. The T-network also includes at least one inductor coupled between an interstage matching network node 430 and a power distribution node, such as a ground node. With a transformer, one inductor may be coupled electrically to the ground node, and another inductor may be coupled electrically to the interstage matching network node 430. The two inductors are electromagnetically coupled together. Accordingly, the driver amplifier 134 may be electromagnetically coupled to the power amplifier 136.

The interstage matching network node 430 may, for instance, be coupled between the first capacitor and the second capacitor. Thus, in the illustrated example, the interstage matching network 140 is realized with a T-network including two capacitors for each of the plus and minus signal paths along the “top” of the T-network and at least one inductor along the “column” of the T-network. The capacitor of the portion of the interstage matching network 140 that is shown in FIG. 6-1 can operate as a capacitor for both the plus and minus signal paths given that the intermediate signal 334 is single ended on the “left” side of the transformer.

At least one inductor of the transformer can be used as part of the T-network for interstage matching. A T-network can, however, be implemented differently. For example, the two capacitors can be swapped with two inductors along the “top” of the T-network, and the inductor can be swapped with a capacitor along the “column” of the T-network. Further, more or different components may be incorporated into the T-network. For instance, a transformer or other balun may be separate from the components of the T-network. Additionally or alternatively, the interstage matching network 140 may be realized with a Pi-network. The Pi-network may include any number of components, including reactive components such as inductor(s) and capacitor(s). An interstage matching network 140 may also be implemented with different networks, more than one network, different components, active or passive components, different couplings between the components, some combination thereof, and so forth.

The plus intermediate signal 334P is coupled to an input of a plus transistor T_P of a differential power amplifier 136. The plus transistor T_P amplifies the plus intermediate signal 334P to produce a plus second amplified signal 332-2P. The plus second amplified signal 332-2P can be forwarded to a plus output (Rf.out_P). The minus intermediate signal 334M is coupled to an input of a minus transistor T_M of the differential power amplifier 136. The minus transistor T_M amplifies the minus intermediate signal 334M to produce a minus second amplified signal 332-2M. The minus second amplified signal 332-2M can be forwarded to a minus output (Rf.out_M).

As shown in FIGS. 6-1 and 6-2, the “B” and “C” connection points can correspond to a plus interstage node (Int_P) and a minus interstage node (Int_M), respectively. These nodes can correspond respectively to a plus node of the interstage matching network 140, or a plus interstage matching network node 430P, and a minus node of the interstage matching network 140, or a minus interstage matching network node 430M. In some aspects, each of the plus interstage matching network node 430P and the minus interstage matching network node 430M can be coupled to the same two clamping circuits 138 (of FIG. 4) using opposite first and second nodes 402-1 and 402-2. Thus, one interstage matching network node 430 can be coupled to a forward-swing configuration of a first clamping circuit 138 (of FIG. 4), and another interstage matching network node 430 can be coupled to a reverse-swing configuration of a second clamping circuit 138. Accordingly, each clamping circuit 138 may be coupled to the plus interstage matching network node 430P and the minus interstage matching network node 430M, but via opposite ones of the first and second nodes 402-1 and 402-2.

In example implementations, the differential clamping circuit 138D of FIG. 5 is coupled to the differential amplifier circuit 130 of FIGS. 6-1 and 6-2 via the plus interstage matching network node 430P and the minus interstage matching network node 430M. With regard to the plus interstage matching network node 430P, the plus “half” of the differential clamping circuit 138D (e.g., the left side as depicted in FIG. 5 with the plus transistor 404P) can protect against forward signal swings at the plus intermediate node Int_P. The minus “half” of the differential clamping circuit 138D (e.g., the right side as depicted in FIG. 5 with the minus transistor 404M), on the other hand, can protect against reverse signal swings at the plus intermediate node Int_P.

With regard to the minus interstage matching network node 430M, the minus “half” of the differential clamping circuit 138D (e.g., the right side as depicted in FIG. 5 with the minus transistor 404M) can protect against forward signal swings at the minus intermediate node Int_M. The plus “half” of the differential clamping circuit 138D (e.g., the left side as depicted in FIG. 5 with the plus transistor 404P), on the other hand, can protect against reverse signal swings at the minus intermediate node Int_M. In these manners, the two differential intermediate nodes Int_P and Int_M can be protected against forward and reverse signal swings using the differential clamping circuit 138D of FIG. 5, which can be formed using two clamping circuits 138 from FIG. 4.

With reference also to FIG. 5, in some cases, the plus interstage matching network node 430P may be coupled to a collector terminal (or drain terminal for FETs) of the plus transistor 404P. The plus interstage matching network node 430P may also be coupled to an emitter terminal (or source terminal for FETs) of the minus transistor 404M. In contrast, the minus interstage matching network node 430M may be coupled to a collector terminal (or drain terminal for FETs) of the minus transistor 404M. The minus interstage matching network node 430M may also be coupled to an emitter terminal (or source terminal for FETs) of the plus transistor 404P.

Although the differential clamping circuit 138D is shown coupled to particular nodes of the example differential interstage matching network 140 of FIGS. 6-1 and 6-2, each differential clamping circuit 138D may be coupled to alternative nodes of the differential amplifier circuit 130, including to different nodes of the differential interstage matching network 140. Further, as described above, the interstage matching network 140 may be realized with a Pi-network, with different components, with more or fewer components, and so forth.

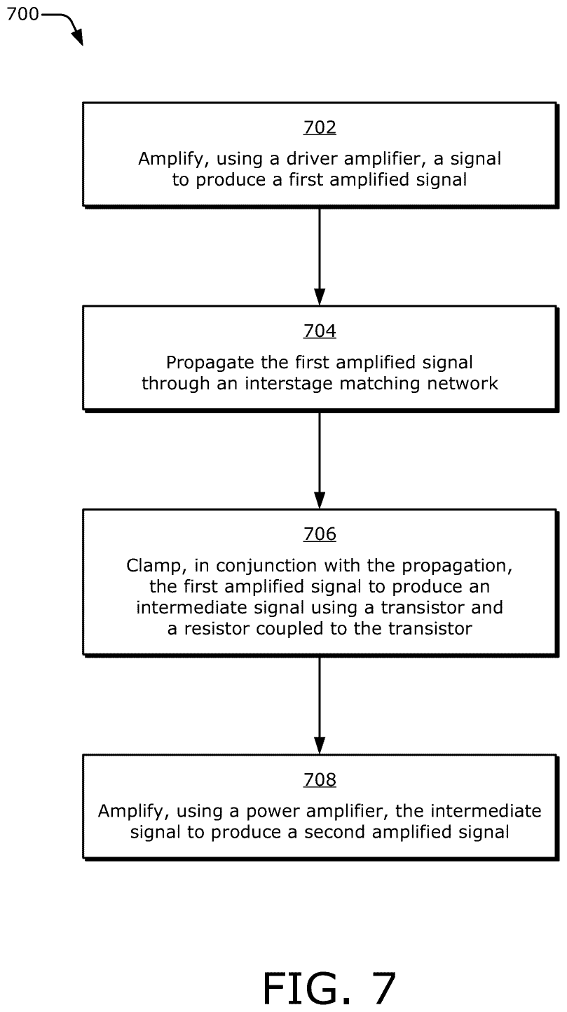

FIG. 7 is a flow diagram illustrating an example process 700 for clamping power by a clamping circuit with respect to an amplifier circuit or for operating a power clamp that is coupled to an interstage matching network. The process 700 includes four blocks 702-708 that specify operations that can be performed for a method. However, operations are not necessarily limited to the order shown in the figures or described herein, for the operations may be implemented in alternative orders or in fully or partially overlapping manners. Also, more, fewer, and/or different operations may be implemented to perform a respective process or an alternative process.

In example implementations, operations represented by the illustrated blocks of each process may be performed by an electronic device, such as the electronic device 102 of FIG. 1 or the wireless interface device 120 thereof. More specifically, the operations of respective processes may be performed by an integrated circuit die (e.g., an amplifier die 304 of FIG. 3 or a die 602 of FIGS. 6-1 and 6-2) or by an amplifier circuit 130 that includes a first amplifier and a second amplifier. Although some of the description herein focusses on amplifiers and power clamps that operate on single-ended signaling or differential signaling in particular, the principles (e.g., corresponding to devices, circuitry, techniques, and processes) that are described with regard to one may also be applicable to the other. In other words, the described principles are generally applicable to differential signaling and single-ended signaling environments.

At block 702, a signal is amplified to produce a first amplified signal using a driver amplifier. For example, an amplifier circuit 130 can amplify a signal 330 to produce a first amplified signal 332-1 using a driver amplifier 134. For instance, a transistor in a common-emitter configuration (or common-source configuration for an FET) of the driver amplifier 134 may amplify a signal that is to be transmitted.

At block 704, the first amplified signal is propagated through an interstage matching network. For example, the amplifier circuit 130 can propagate the first amplified signal 332-1 through an interstage matching network 140. In some cases, the interstage matching network 140 may include a T-network or a Pi-network and may operate on single-ended or differential signaling. Further, the interstage matching network 140 may include a balun, such as a transformer, to convert as single-ended first amplified signal 332-1 to a differential signal.

At block 706, in conjunction with the propagating, the first amplified signal is clamped to produce an intermediate signal using a transistor and a resistor coupled to the transistor. For example, the amplifier circuit 130 can clamp, in conjunction with the signal propagation through the interstage matching network 140, the first amplified signal 332-1 to produce an intermediate signal 334 using at least one transistor 404 and at least one resistor 408 that is coupled to the transistor 404. To do so, one or more of a forward-swing configuration of the clamping circuit 138, a reverse-swing configuration of the clamping circuit 138, or a differential clamping circuit 138D may clamp the intermediate signal 334 to produce a clamped signal having a reduced voltage or current. The resistor 408 may be coupled between two terminals of the transistor 404, such as between a control terminal and a channel terminal.

At block 708, the intermediate signal is amplified to produce a second amplified signal using a power amplifier. For example, the amplifier circuit 130 can amplify the intermediate signal 334 to produce a second amplified signal 332-2 using a power amplifier 136. Thus, with a power of the intermediate signal 334 clamped by at least one clamping circuit 138, the power amplifier 136 may safely amplify the clamped intermediate signal 334 with at least one transistor T without damaging the at least one transistor T. In some cases, the at least one transistor T can include a plus transistor T_P and a minus transistor T_M for differential signaling.

In example aspects, the clamping circuit 130 can further increase a balancing of the clamping between plus and minus voltage swings of differential signaling, based, for instance, on routing current through plus and minus resistors 408P and 408M of a differential clamping circuit 138D.

In some aspects, the transistor 404 can include a plus transistor 404P, and the resistor 408 can include a plus resistor 408P. In at least some of such cases, the plus resistor 408P can be coupled between a control terminal of the plus transistor 404P and a first channel terminal of the plus transistor 404P (e.g., an emitter terminal of an HBT). The clamping of block 706 can include clamping the first amplified signal 332-1 using a minus transistor 404M and a minus resistor 408M. Here, the minus resistor 408M may be coupled between a control terminal of the minus transistor 404M and a second channel terminal of the plus transistor 404P (e.g., a collector terminal of an HBT).

### Implementation Examples

This section describes some aspects of example implementations and/or example configurations related to the apparatuses and/or processes presented above.

Example aspect 1: An apparatus comprising:
an amplifier circuit including an input port and an output port, the amplifier circuit comprising:
   a driver amplifier including a driver amplifier output, the driver amplifier coupled between the input port and the output port;
   a power amplifier including a power amplifier input, the power amplifier coupled between the driver amplifier output and the output port;
   an interstage matching network coupled between the driver amplifier output and the power amplifier input; and
   a clamping circuit coupled to the interstage matching network via a node that is coupled between the driver amplifier output and the power amplifier input, the clamping circuit comprising a transistor and a resistor coupled to the transistor.

Example aspect 2: The apparatus of example aspect 1, wherein the resistor is coupled between two terminals of the transistor.

Example aspect 3: The apparatus of example aspect 2, wherein:
the two terminals of the transistor comprise a control terminal and a channel terminal; and
the resistor is coupled between the control terminal of the transistor and the channel terminal of the transistor.

Example aspect 4: The apparatus of example aspect 3, wherein:
the transistor comprises a bipolar junction transistor (BJT);
the control terminal of the transistor comprises a base terminal of the bipolar junction transistor; and
the channel terminal of the transistor comprises an emitter terminal of the bipolar junction transistor.

Example aspect 5: The apparatus of any one of the preceding example aspects, further comprising:
an integrated circuit die that comprises the amplifier circuit,
wherein the clamping circuit is configured to provide power clamping for a signal that propagates from the driver amplifier output to the power amplifier input.

Example aspect 6: The apparatus of any one of the preceding example aspects, wherein the node is coupled between a channel terminal of a transistor of the driver amplifier and a control terminal of a transistor of the power amplifier.

Example aspect 7: The apparatus of any one of the preceding example aspects, wherein the interstage matching network comprises a T-network.

Example aspect 8: The apparatus of example aspect 7, wherein the T-network comprises:
a first capacitor coupled between the driver amplifier output and the power amplifier input;
a second capacitor coupled between the driver amplifier output and the power amplifier input; and
at least one inductor coupled between an interstage matching network node and a power distribution node, the interstage matching network node coupled between the first capacitor and the second capacitor.

Example aspect 9: The apparatus of example aspect 8, wherein:
the at least one inductor comprises two or more inductors electromagnetically coupled together to form at least one transformer; and
the node that is coupled between the driver amplifier output and the power amplifier input corresponds to the interstage matching network node.

Example aspect 10: The apparatus of any one of the preceding example aspects, wherein the interstage matching network comprises a Pi-network.

Example aspect 11: The apparatus of any one of the preceding example aspects, wherein:
the transistor comprises a control terminal and a channel terminal;
the clamping circuit comprises one or more diodes coupled between the control terminal and the channel terminal of the transistor; and
the channel terminal of the transistor is coupled to the node.

Example aspect 12: The apparatus of example aspect 11, wherein:
the one or more diodes comprise multiple diodes coupled together in series between the control terminal and the channel terminal of the transistor; and
the clamping circuit is configured to clamp a voltage at the node responsive to a voltage level that is based, at least partly, on a quantity of diodes of the multiple diodes.

Example aspect 13: The apparatus of example aspect 12, wherein the clamping circuit is configured to increase a clamping action on the voltage at the node as the voltage at the node increases.

Example aspect 14: The apparatus of any one of the preceding example aspects, wherein:
the transistor comprises a plus transistor of the clamping circuit, and the resistor comprises a plus resistor of the clamping circuit;
the plus transistor is coupled between a plus node of the interstage matching network and a minus node of the interstage matching network;
the clamping circuit comprises a minus transistor and a minus resistor coupled to the minus transistor; and
the minus transistor is coupled between the plus node of the interstage matching network and the minus node of the interstage matching network.

Example aspect 15: The apparatus of example aspect 14, wherein:
a first channel terminal of the plus transistor is coupled to the plus node of the interstage matching network, and a second channel terminal of the plus transistor is coupled to the minus node of the interstage matching network; and
a first channel terminal of the minus transistor is coupled to the minus node of the interstage matching network, and a second channel terminal of the minus transistor is coupled to the plus node of the interstage matching network.

Example aspect 16: The apparatus of example aspect 15, wherein:
the first channel terminal of the plus transistor comprises a collector terminal of the plus transistor, and the second channel terminal of the plus transistor comprises an emitter terminal of the plus transistor; and
the first channel terminal of the minus transistor comprises a collector terminal of the minus transistor, and the second channel terminal of the minus transistor comprises an emitter terminal of the minus transistor.

Example aspect 17: The apparatus of example aspect 15 or 16, wherein:
the plus resistor is coupled between a control terminal of the plus transistor and the minus node of the interstage matching network; and
the minus resistor is coupled between a control terminal of the minus transistor and the plus node of the interstage matching network.

Example aspect 18: The apparatus of any one of the preceding example aspects, further comprising:
a wireless interface device comprising the amplifier circuit.

Example aspect 19: The apparatus of example aspect 18, further comprising:
a display screen; and
one or more processors operatively coupled to the display screen and at least a portion of the wireless interface device, the one or more processors configured to present one or more graphical images on the display screen based on one or more wireless signals communicated using the amplifier circuit of the wireless interface device.

Example aspect 20: An apparatus comprising:
an amplifier circuit including an input port and an output port, the amplifier circuit comprising:
   a driver amplifier including a driver amplifier input and a driver amplifier output, the driver amplifier input coupled to the input port;
   a power amplifier including a power amplifier input and a power amplifier output, the power amplifier output coupled to the output port;
   an interstage matching network coupled between the driver amplifier output and the power amplifier input; and
   means for clamping a power of a signal flowing through the interstage matching network between the driver amplifier and the power amplifier using a transistor and a resistor coupled to the transistor.

Example aspect 21: The apparatus of example aspect 20, wherein:
the power amplifier comprises a differential power amplifier, and the signal comprises a differential signal; and
the amplifier circuit further comprises means for balancing plus and minus clamping of the differential signal.

Example aspect 22: A method comprising:
amplifying, using a driver amplifier, a signal to produce a first amplified signal;
propagating the first amplified signal through an interstage matching network;
clamping, in conjunction with the propagating, the first amplified signal to produce an intermediate signal using a transistor and a resistor coupled to the transistor; and
amplifying, using a power amplifier, the intermediate signal to produce a second amplified signal.

Example aspect 23: The method of example aspect 22, wherein the clamping comprises:
increasing a balancing of the clamping between plus and minus voltage swings of differential signaling.

Example aspect 24: The method of example aspect 22 or 23, wherein:
the transistor comprises a plus transistor, and the resistor comprises a plus resistor;
the plus resistor is coupled between a control terminal of the plus transistor and a first channel terminal of the plus transistor; and
the clamping comprises clamping the first amplified signal using a minus transistor and a minus resistor, the minus resistor coupled between a control terminal of the minus transistor and a second channel terminal of the plus transistor.

### CONCLUSION

As used herein, the terms “couple,” “coupled,” or “coupling” refer to a relationship between two or more components that are in operative communication with each other to implement some feature or realize some capability that is described herein. The coupling can be realized using, for instance, a physical line, such as a metal trace or wire, or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “port” (e.g., including a “first port” or an “amplifier port”) represents at least a point of electrical connection at or proximate to the input or output of a component or between two or more components (e.g., active or passive circuit elements or parts). Although at times a port may be visually depicted in a drawing as a single point (or a circle), the port can represent an inter-connected portion of a physical circuit or network that has at least approximately a same voltage potential at or along the portion. In other words, a single-ended port can represent at least one point (e.g., a node) of multiple points along a conducting medium (e.g., a wire or trace) that exists between electrically connected components. In some cases, a “port” can represent at least one node that represents or corresponds to an input or an output of a component, such as a matching network, an amplifier circuit, or a portion thereof. Similarly, a “terminal” or a “node” may represent one or more points with at least approximately a same voltage potential, with a terminal being relative to an input or output of a component.

The terms “first,” “second,” “third,” and other numeric-related indicators are used herein to identify or distinguish similar or analogous items from one another within a given context-such as a particular implementation, a single drawing figure, a given component, or a claim. Thus, a first item in one context may differ from a first item in another context. For example, an item identified as a “first signal” in one context may be identified as a “second signal” in another context. Similarly, a “first port” or a “first transistor” in one claim may be recited as a “second port” or a “third transistor,” respectively, in a different claim.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing an interstage clamping circuit have been described in language specific to certain features and/or methods, the subject of the appended claims is not necessarily limited to the specific features or methods described. Rather, the specific features and methods are disclosed as example implementations for realizing an interstage clamping circuit.

What is claimed is:

1. An apparatus comprising:
an amplifier circuit including an input port and an output port, the amplifier circuit comprising:
a driver amplifier including a driver amplifier output, the driver amplifier coupled between the input port and the output port;
a power amplifier including a power amplifier input, the power amplifier coupled between the driver amplifier output and the output port;
an interstage matching network coupled between the driver amplifier output and the power amplifier input; and
a clamping circuit coupled to the interstage matching network via a node that is coupled between the driver amplifier output and the power amplifier input, the clamping circuit comprising a transistor and a resistor coupled to the transistor.

2. The apparatus of claim 1, wherein the resistor is coupled between two terminals of the transistor.

3. The apparatus of claim 2, wherein:
the two terminals of the transistor comprise a control terminal and a channel terminal; and
the resistor is coupled between the control terminal of the transistor and the channel terminal of the transistor.

4. The apparatus of claim 3, wherein:
the transistor comprises a bipolar junction transistor (BJT);
the control terminal of the transistor comprises a base terminal of the bipolar junction transistor; and
the channel terminal of the transistor comprises an emitter terminal of the bipolar junction transistor.

5. The apparatus of claim 1, further comprising:
an integrated circuit die that comprises the amplifier circuit,
wherein the clamping circuit is configured to provide power clamping for a signal that propagates from the driver amplifier output to the power amplifier input.

6. The apparatus of claim 1, wherein the node is coupled between a channel terminal of a transistor of the driver amplifier and a control terminal of a transistor of the power amplifier.

7. The apparatus of claim 1, wherein the interstage matching network comprises a T-network.

8. The apparatus of claim 7, wherein the T-network comprises:
a first capacitor coupled between the driver amplifier output and the power amplifier input;
a second capacitor coupled between the driver amplifier output and the power amplifier input; and
at least one inductor coupled between an interstage matching network node and a power distribution node, the interstage matching network node coupled between the first capacitor and the second capacitor.

9. The apparatus of claim 8, wherein:
the at least one inductor comprises two or more inductors electromagnetically coupled together to form at least one transformer; and
the node that is coupled between the driver amplifier output and the power amplifier input corresponds to the interstage matching network node.

10. The apparatus of claim 1, wherein the interstage matching network comprises a Pi-network.

11. The apparatus of claim 1, wherein:
the transistor comprises a control terminal and a channel terminal;
the clamping circuit comprises one or more diodes coupled between the control terminal and the channel terminal of the transistor; and
the channel terminal of the transistor is coupled to the node.

12. The apparatus of claim 11, wherein:
the one or more diodes comprise multiple diodes coupled together in series between the control terminal and the channel terminal of the transistor; and
the clamping circuit is configured to clamp a voltage at the node responsive to a voltage level that is based, at least partly, on a quantity of diodes of the multiple diodes.

13. The apparatus of claim 12, wherein the clamping circuit is configured to increase a clamping action on the voltage at the node as the voltage at the node increases.

14. The apparatus of claim 1, wherein:
the transistor comprises a plus transistor of the clamping circuit, and the resistor comprises a plus resistor of the clamping circuit;
the plus transistor is coupled between a plus node of the interstage matching network and a minus node of the interstage matching network;
the clamping circuit comprises a minus transistor and a minus resistor coupled to the minus transistor; and
the minus transistor is coupled between the plus node of the interstage matching network and the minus node of the interstage matching network.

15. The apparatus of claim 14, wherein:
a first channel terminal of the plus transistor is coupled to the plus node of the interstage matching network, and a second channel terminal of the plus transistor is coupled to the minus node of the interstage matching network; and
a first channel terminal of the minus transistor is coupled to the minus node of the interstage matching network, and a second channel terminal of the minus transistor is coupled to the plus node of the interstage matching network.

16. The apparatus of claim 15, wherein:
the first channel terminal of the plus transistor comprises a collector terminal of the plus transistor, and the second channel terminal of the plus transistor comprises an emitter terminal of the plus transistor; and
the first channel terminal of the minus transistor comprises a collector terminal of the minus transistor, and the second channel terminal of the minus transistor comprises an emitter terminal of the minus transistor.

17. The apparatus of claim 15, wherein:
the plus resistor is coupled between a control terminal of the plus transistor and the minus node of the interstage matching network; and
the minus resistor is coupled between a control terminal of the minus transistor and the plus node of the interstage matching network.

18. The apparatus of claim 1, further comprising:
a wireless interface device comprising the amplifier circuit.

19. The apparatus of claim 18, further comprising:
a display screen; and
one or more processors operatively coupled to the display screen and at least a portion of the wireless interface device, the one or more processors configured to present one or more graphical images on the display screen based on one or more wireless signals communicated using the amplifier circuit of the wireless interface device.

20. An apparatus comprising:
an amplifier circuit including an input port and an output port, the amplifier circuit comprising:
a driver amplifier including a driver amplifier input and a driver amplifier output, the driver amplifier input coupled to the input port;
a power amplifier including a power amplifier input and a power amplifier output, the power amplifier output coupled to the output port;
an interstage matching network coupled between the driver amplifier output and the power amplifier input; and
means for clamping a power of a signal flowing through the interstage matching network between the driver amplifier and the power amplifier using a transistor and a resistor coupled to the transistor.

21. The apparatus of claim 20, wherein:
the power amplifier comprises a differential power amplifier, and the signal comprises a differential signal; and
the amplifier circuit further comprises means for balancing plus and minus clamping of the differential signal.

22. A method comprising:
amplifying, using a driver amplifier, a signal to produce a first amplified signal;
propagating the first amplified signal through an interstage matching network;
clamping, in conjunction with the propagating, the first amplified signal to produce an intermediate signal using a transistor and a resistor coupled to the transistor; and
amplifying, using a power amplifier, the intermediate signal to produce a second amplified signal.

23. The method of claim 22, wherein the clamping comprises:
increasing a balancing of the clamping between plus and minus voltage swings of differential signaling.

24. The method of claim 22, wherein:
the transistor comprises a plus transistor, and the resistor comprises a plus resistor;
the plus resistor is coupled between a control terminal of the plus transistor and a first channel terminal of the plus transistor; and
the clamping comprises clamping the first amplified signal using a minus transistor and a minus resistor, the minus resistor coupled between a control terminal of the minus transistor and a second channel terminal of the plus transistor.
